(19) United States
(12) Patent Application Publication
(10) Pub. No.: US 2019/0087126 A1
(43) Pub. Date: Mar. 21, 2019

(54) MEMORY SYSTEM AND OPERATING METHOD OF MEMORY SYSTEM

(71) Applicant: SK hynix Inc., Gyeonggi-do (KR)

(72) Inventor: Dong-Yeob CHUN, Seoul (KR)

(21) Appl. No.: 15/936,756

(22) Filed: Mar. 27, 2018

(30) Foreign Application Priority Data
Sep. 18, 2017 (KR) 10-2017-0119414

(51) Int. Cl. G06F 3/06

(52) U.S. Cl. CPC G06F 3/0659; G11C 16/0483; G06F 3/0679; G06F 3/0611

(57) ABSTRACT

A memory system includes: one or more memory devices each including a plurality of memory dies each having a plurality of planes; and a controller including: a random command queue suitable for queueing a plurality of random read commands; a multi-read command queue suitable for queueing at least merged random read commands; a read rule checker suitable for storing a multi-read rule representing a direction for selecting two or more among the planes; a command arbitrator suitable for merging two or more random read commands satisfying the multi-read rule among the random read commands queued in the random read commands, and queueing at least the merged random read commands in the multi-read command queue; and a processor suitable for controlling the memory devices to perform a multi-plane read operation according to the merged random read commands in the multi-read command queue.

### CROSS-REFERENCE TO RELATED APPLICATION

The present application claims priority under 35 U.S.C. § 119(a) to Korean Patent Application No. 10-2017-0119414 filed on Sep. 18, 2017, the disclosure of which is incorporated herein by reference in its entirety.

### TECHNICAL FIELD

Various embodiments of the present invention generally relate to a memory system. Particularly, the embodiments relate to a memory system that can perform a multi-read operation on a memory device, and an operating method of the memory system.

### DISCUSSION OF THE RELATED ART

The computer environment paradigm has recently been transitioning into ubiquitous computing, which enables computing systems to be used anytime and anywhere. As a result, use of portable electronic devices such as mobile phones, digital cameras, and laptop computers has increased. These portable electronic devices generally use a memory system having one or more memory devices for storing data. A memory system may be used as a main memory device or an auxiliary memory device of a portable electronic device.

Since the memory systems have no moving parts, the memory systems provide excellent stability, durability, high information access speed, and low power consumption. Examples of memory systems having such advantages include universal serial bus (USB) memory devices, memory cards having various interfaces, and solid state drives (SSD).

### SUMMARY

Various embodiments are directed to a memory system for processing random read commends. Provided are the memory system may perform a multi-read operation on a memory device by merging the random read commands according to a multi-read rule and an operating method of the memory system.

In accordance with an embodiment of the present invention, a memory system may include: one or more memory devices each including a plurality of memory dies each having a plurality of planes; and a controller including: a random command queue suitable for queueing a plurality of random read commands; a multi-read command queue suitable for queueing at least merged random read commands; a read rule checker suitable for storing a multi-read rule representing a direction for selecting two or more among the planes; a command arbitrator suitable for merging two or more random read commands satisfying the multi-read rule among the random read commands queued in the random read commands, and queueing at least the merged random read commands in the multi-read command queue; and a processor suitable for controlling the memory devices to perform a multi-plane read operation according to the merged random read commands in the multi-read command queue.

The multi-read rule may be a read rule for performing a multi-read operation on the read units close to each other among a plurality of read units included in the first memory device.

The multi-read rule may be a read rule for performing a multi-read operation on the read units not close to each other among a plurality of read units included in the first memory device.

The multi-read rule unit may be a read rule for performing a multi-read operation for read units included in different memory devices and corresponding to each other.

The processor may control the memory devices to further perform a single read operation in accordance with a random read command input to the multi-read command queue and other than the merged random read commands.

In accordance with an embodiment of the present invention, an operating method of memory system including one or more memory devices each including a plurality of memory dies each having a plurality of planes includes: queueing a plurality of random read commands into a random command queue; merging two or more random read commands satisfying a multi-read rule, which represents a direction for selecting two or more among the planes, among the random read commands queued in the random read commands; queueing at least the merged random read commands in a multi-read command queue; and controlling the memory devices to perform a multi-plane read operation according to the merged random read commands in the multi-read command queue.

The multi-read rule may be a read rule for performing a multi-read operation on the read units close to each other among a plurality of read units included in the first memory device.

The multi-read rule may be a read rule for performing a multi-read operation on the read units not close to each other among a plurality of read units included in the first memory device.

The multi-read rule unit may be a read rule for performing a multi-read operation for read units included in different memory devices and corresponding to each other.

The memory system may comprise controlling the memory devices to perform a single read operation in accordance with a random read command input to the multi-read command queue and other than the merged random read commands.

In accordance with an embodiment of the present invention, a memory system may include: one or more memory devices each including a plurality of memory dies each having a plurality of planes; and a controller suitable for: selecting two or more planes among the plurality of planes; merging random read commands corresponding to the selected planes; and controlling the memory devices to perform a multi-plane read operation according to the merged random read commands.

The controller may select two or more adjacent planes among the plurality of planes of the respective memory dies in the respective memory devices.

The controller may select two or more non-adjacent planes among the plurality of planes of the respective memory dies in the respective memory devices.

The controller may select two or more same planes of different memory devices, respectively, among the plurality of planes of the memory dies in the memory devices.

In accordance with an embodiment of the present invention. An operating method of a memory system including one or more memory devices each including a plurality of memory dies each having a plurality of planes may include: selecting two or more planes among the plurality of planes; merging random read commands corresponding to the selected planes; and controlling the memory devices to perform a multi-plane read operation according to the merged random read commands.

The selecting may include selecting two or more adjacent planes among the plurality of planes of the respective memory dies in the respective memory devices.

The selecting may include selecting two or more non-adjacent planes among the plurality of planes of the respective memory dies in the respective memory devices.

The selecting may include selecting two or more same planes of different memory devices, respectively, among the plurality of planes of the memory dies in the memory devices.

In accordance with various embodiments of the present invention, the memory system may perform the multi-read operation by merging the random read commands, thereby reducing the unnecessary delay between single read command transfer operations. Therefore, the overall read operation may be simplified, and the time required for performing the read operation may be shortened.

### BRIEF DESCRIPTION OF THE DRAWINGS

FIG. 1 is a block diagram illustrating a data processing system in accordance with an embodiment of the present invention.

FIG. 2 is a schematic diagram illustrating a memory device shown in FIG. 1.

FIG. 3 is a circuit diagram illustrating a memory block in a memory device shown in FIG. 1.

FIG. 4 is a schematic diagram illustrating a 3D structure of the memory device shown in FIG. 1.

FIGS. 5 to 8B are schematic diagrams describing the multi-read operation for the memory device of the controller in the memory system in accordance with an embodiment of the present invention.

FIG. 9 is a flow chart describing the multi-read operation for the memory device of the controller in the memory system in accordance with an embodiment of the present invention.

FIGS. 10 to 18 are schematic diagrams illustrating various examples of data processing system including memory system in accordance with an embodiment of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

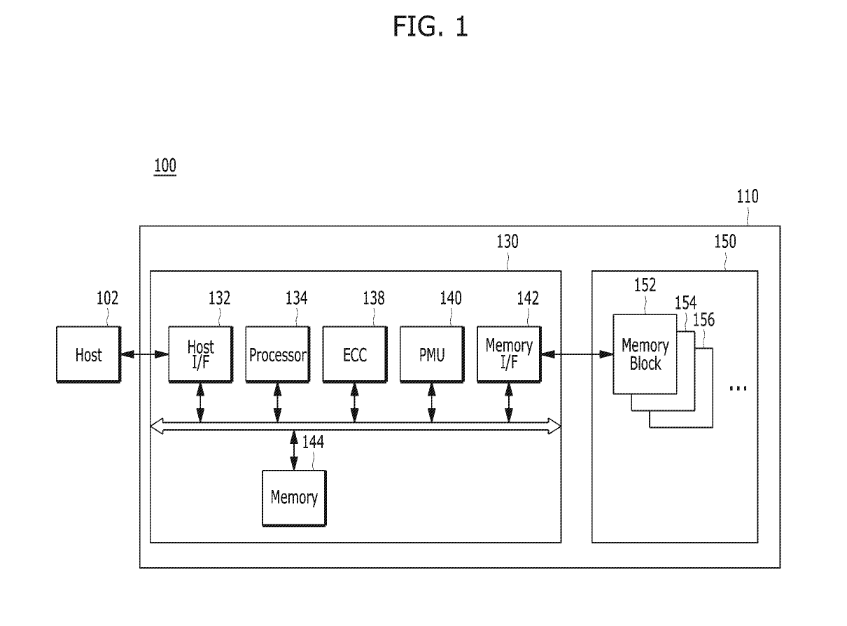

FIG. 1 is a block diagram illustrating a data processing system 100 in accordance with an embodiment of the present invention.

Referring to FIG. 1, the data processing system 100 may include a host 102 operatively coupled to a memory system 110.

The host 102 may include portable electronic devices such as a mobile phone, an MP3 player, and a laptop computer or non-portable electronic devices such as a desktop computer, a game player, a TV, a projector, and the like.

The memory system 110 may operate to store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card, and a memory stick. The MMC may include an embedded MMC (eMMC), a reduced size MMC (RS-MMC), and a micro-MMC. The SD card may include a mini-SD card and a micro-SD card.

The memory system 110 may be embodied by various types of storage devices. Non-limited examples of storage devices included in the memory system 110 may include volatile memory devices such as a dynamic random access memory (DRAM) and a static RAM (SRAM), and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), a resistive RAM (RRAM), and a flash memory. The flash memory may have a 3-dimensioanl (3D) stack structure.

The memory system 110 may include a memory device 150 and a controller 130. The memory device 150 may store data for the host 120, and the controller 130 may control data storage into the memory device 150.

The controller 130 and the memory device 150 may be integrated into a single semiconductor device, which may be included in the various types of memory systems as exemplified above.

Non-limited application examples of the memory system 110 may include a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation system, a black box, a digital camera, a digital multimedia broadcasting (DMB) player, a 3D television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, a radio frequency identification (RFID) device, or one of various component elements configuring a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory dies (not shown), each memory die including a plurality of planes (not shown), each plane including a plurality of memory blocks 152 to 156, each of the memory blocks 152 to 156 may include a plurality of pages, and each of the pages may include a plurality of memory cells coupled to a word line.

The controller 130 may control the memory device 150 in response to a request from the host 102. For example, the controller 130 may provide data read from the memory device 150 to the host 102, and store data provided from the host 102 into the memory device 150. The controller 130 may control read, write, program and erase operations of the memory device 150.

The controller 130 may include a host interface (I/F) unit 132, a processor 134, an error correction code (ECC) unit 138, a power management unit (PMU) 140, a memory I/F 142, and a memory 144 all operatively coupled via an internal bus.

The host interface unit 132 may process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (PATA), enhanced small disk interface (ESDI), and integrated drive electronics (IDE).

The ECC unit 138 may correct error bits of data to be processed by the memory device 150 and may include an ECC encoder and an ECC decoder. The ECC encoder may perform an error correction encoding on data to be programmed into the memory device 150 to generate data to which a parity bit is added. The data including the parity bit may be stored in the memory device 150. The ECC decoder may detect and correct an error contained in the data read from the memory device 150. In other words, the ECC unit 138 may perform an error correction decoding process on the data read from the memory device 150 through an ECC code used during an ECC encoding process. According to a result of the error correction decoding process, the ECC unit 138 may output a signal, for example, an error correction success/fail signal. When the number of error bits is more than a threshold value of correctable error bits, the ECC unit 138 may not correct the error bits, and may output an error correction fail signal.

The ECC unit 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM), and Block coded modulation (BCM). However, the ECC unit 138 of the present disclosure is not limited thereto. That is, the ECC unit 138 may include all circuits, modules, systems, or devices for error correction.

The PMU 140 may provide and manage power of the controller 130.

The memory I/F 142 may serve as a memory/storage interface for interfacing the controller 130 and the memory device 150 such that the controller 130 controls the memory device 150 in response to a request from the host 102. When the memory device 150 is a flash memory such as a NAND flash memory, the memory I/F 142 may generate a control signal for the memory device 150 and process data to be provided to the memory device 150 under the control of the processor 134. The memory I/F 142 may work as an interface (e.g., a NAND flash interface) for processing a command and data between the controller 130 and the memory device 150. Specifically, the memory I/F 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program, and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. Although FIG. 1 exemplifies the memory 144 disposed within the controller 130, the present disclosure is not limited thereto. That is, in an embodiment, the memory 144 may be embodied by an external volatile memory having a memory interface transferring data between the memory 144 and the controller 130.

The processor 134 may control the overall operations of the memory system 110. The processor 134 may drive firmware to control the overall operations of the memory system 110. The firmware may be referred to as flash translation layer (FTL).

The processor 134 of the controller 130 may include a management unit (not illustrated) for performing a bad management operation of the memory device 150. The management unit may perform a bad block management operation of detecting a bad block, in which a program fail occurs among the plurality of memory blocks 152 to 156 during a program operation due to the characteristic of a NAND flash memory. The management unit may also write the program-failed data of the bad block into a new memory block. In the memory device 150 having a 3D stack structure, the bad block management operation may increase the use efficiency of the memory device 150 and the reliability of the memory system 110.

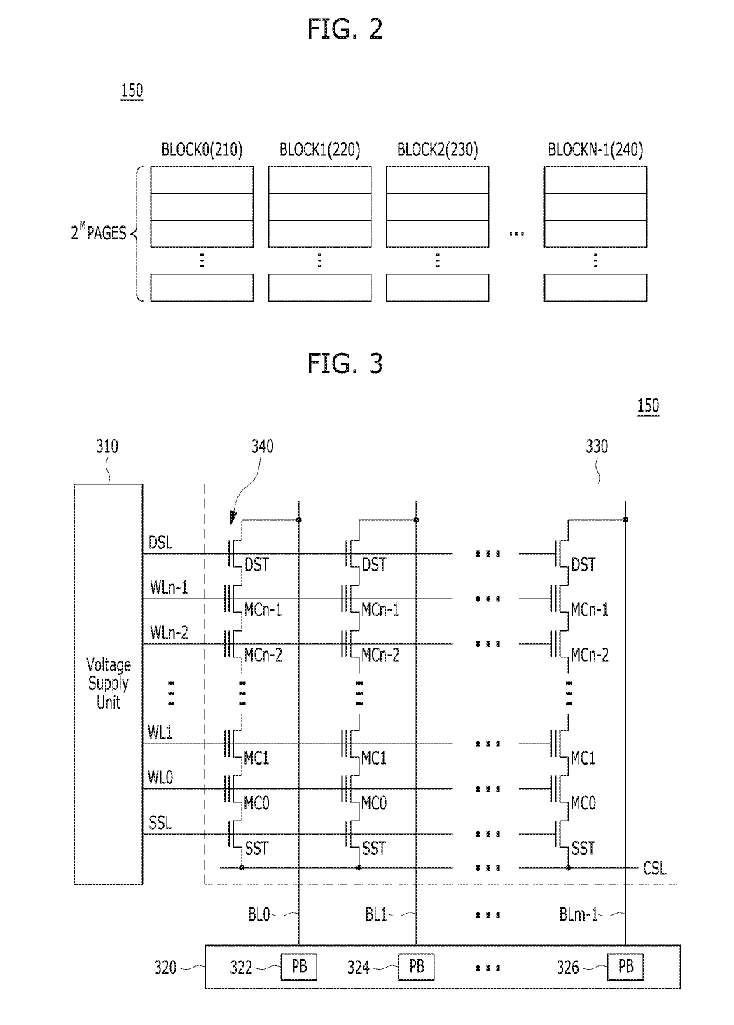

FIG. 2 is a schematic diagram illustrating the memory device 150 shown in FIG. 1.

Referring to FIG. 2, the memory device 150 may include the plurality of memory blocks BLOCK0 to BLOCKN-1, and each of the blocks BLOCK0 to BLOCKN-1 may include a plurality of pages, for example, 2^{M} pages, the number of which may vary depending on circuit design. Memory cells included in the respective memory blocks BLOCK0 to BLOCKN-1 may be one or more of a single level cell (SLC) storing 1-bit data, a multi-level cell (MLC) storing 2-bit data, a triple level cell (TLC) storing 3-bit data, a quadruple level cell (QLC) storing 4-bit level cell, a multiple level cell storing 5-or-more-bit data, and so forth.

FIG. 3 is a circuit diagram illustrating a memory block 330 in the memory device 150 shown in FIG. 1. Specifically, the memory block 330 of FIG. 3 may correspond to any of the plurality of memory blocks 152 to 156 shown in FIG. 1.

Referring to FIG. 3, the memory block 330 of the memory device 150 may include a plurality of cell strings 340 electrically coupled to bit lines BL0 to BLm-1, respectively. The cell string 340 of each column may include one or more drain select transistors DST and one or more source select transistors SST. Between drain and the select transistors DST and SST, a plurality of memory cells MC0 to MCn-1 may be coupled in series. In an embodiment, each of the memory cell transistors MC0 to MCn-1 may be embodied by an MLC capable of storing data information of a plurality of bits. Each of the cell strings 340 may be electrically coupled to a corresponding one among the bit lines BL0 to BLm-1. For example, as illustrated in FIG. 3, the first cell string is coupled to the first bit line BL0, and the last cell string is coupled to the last bit line BLm-1.

Although FIG. 3 illustrates NAND flash memory cells, the invention is not limited in this way. It is noted that the memory cells may be NOR flash memory cells, or hybrid flash memory cells including two or more kinds of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply unit 310 which provides word line voltages including a program voltage, a read voltage, and a pass voltage to supply to the word lines according to an operation mode. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines as may be needed.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

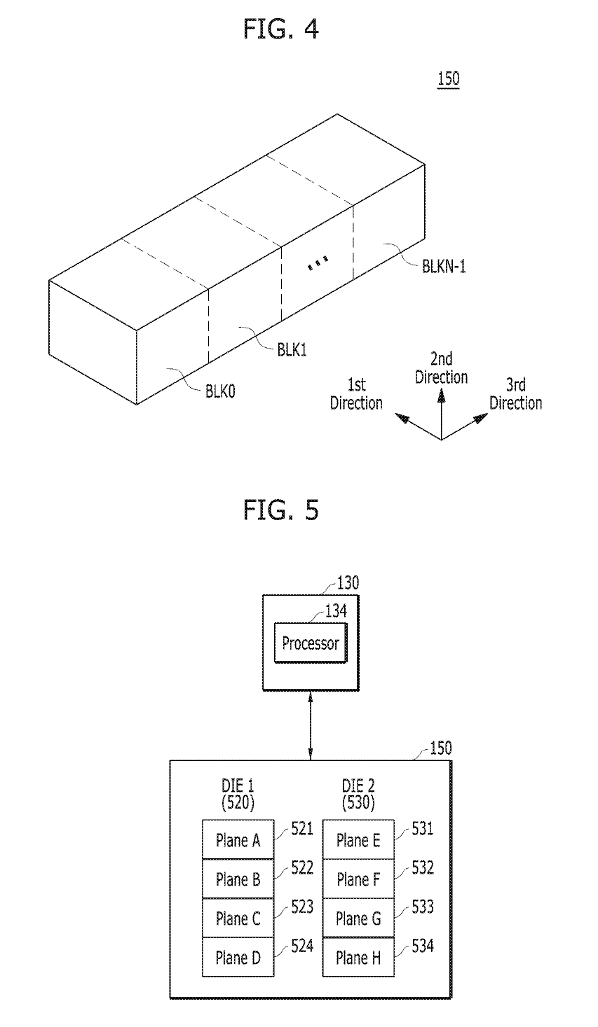

FIG. 4 is a schematic diagram illustrating a 3D structure of the memory device 150 shown in FIG. 1.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN-1 each having a 3D structure (or vertical structure).

Hereinafter, the multi-read operation for the memory device 150 according to an embodiment of the present invention will be described in more detail with reference to FIGS. 5 to 8.

FIG. 5 shows a configuration diagram of the memory system 110.

As described with reference to FIG. 1, the controller 130 may control the memory device 150 to perform a read operation.

The memory device 150 may include a plurality of memory dies. For example, the memory device 150 may include a first memory die 520 and a second memory die 530.

Each of the first memory die 520 and the second memory die 530 include a plurality of planes. For example, the first memory die 520 may include a plane A 521, a plane B 522, a plane C 523, and a plane D 524, and the second memory die 530 may include a plane E 531, a plane F 532, a plane G 533, and a plane H 534.

In an embodiment of the present invention, for convenience of explanation, the controller 130 may control the memory device 150 to perform a read operation by units of pages or by units of memory blocks.

The processor 134 may process a read command received from the host 102 through firmware called a FTL (Flash Translation Layer) and performs a read operation on the memory device 150. The read operation may be one of a sequential read operation and a random read operation.

When the processor 134 receives a sequential read command from the host 102, the processor 134 may control the memory device 150 to perform a sequential read operation through a single read command transfer or a multi read command transfer.

When the processor 134 controls the memory device 150 to perform a sequential read operation, because the sequential read command is sequentially inputted to the processor 134, the processor 134 may easily perform the multi-read command transfer. Specifically, as one example of a sequential read operation, when the processor 134 receives from the host 102 read commands sequentially for the plane A 521, plane B 522, plane C 523, and plane D 524 included in the first memory die 520, the processor 134 may merge the read commands and perform multi-read command transfer. When the multi-read command transfer is performed, the unnecessary delays between a plurality of single read command transfer operations are reduced as compared to the case of a plurality of the single read command transfer operations, and the overall read operation is simplified. Therefore, an advantage may be that the time required for performing a sequential read operation is shortened.

When the processor 134 receives a random read command from the host 102, the processor 134 may control the memory device 150 to perform a random read operation through the single read command transfer operation. Specifically, as one example of a random read operation, when the processor 134 randomly receives from the host 102 read commands for each of the plane A 521, the plane B 522, the plane C 523, the plane D 524 included in the first memory die 520 and for each of the plane E 531, the plane F 532, the plane G 533, the plane H 534 included in the second memory die 520, because the processor 134 can not merge the randomly received read commands, the processor must perform a plurality of single read command transfer operations. In order to perform the multi-read command transfer on the randomly received read commands, after the processor 134 sequentially arranges the randomly received read commands according to a multi-read rule, the processor 134 merges the arranged random read commands and performs the multi-read command transfer.

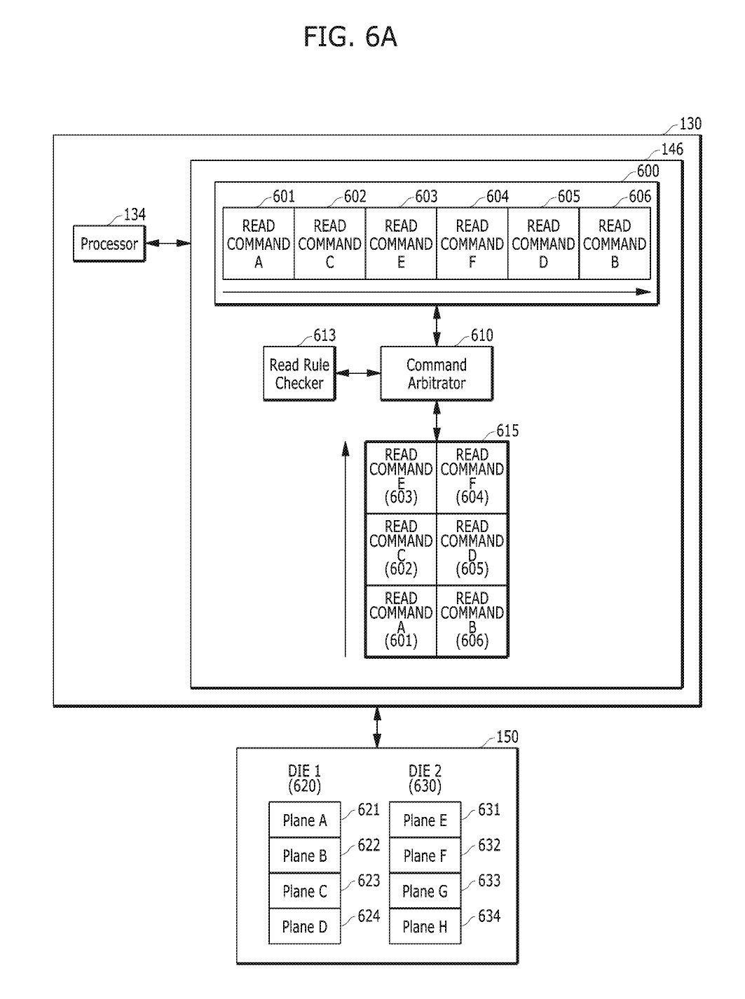

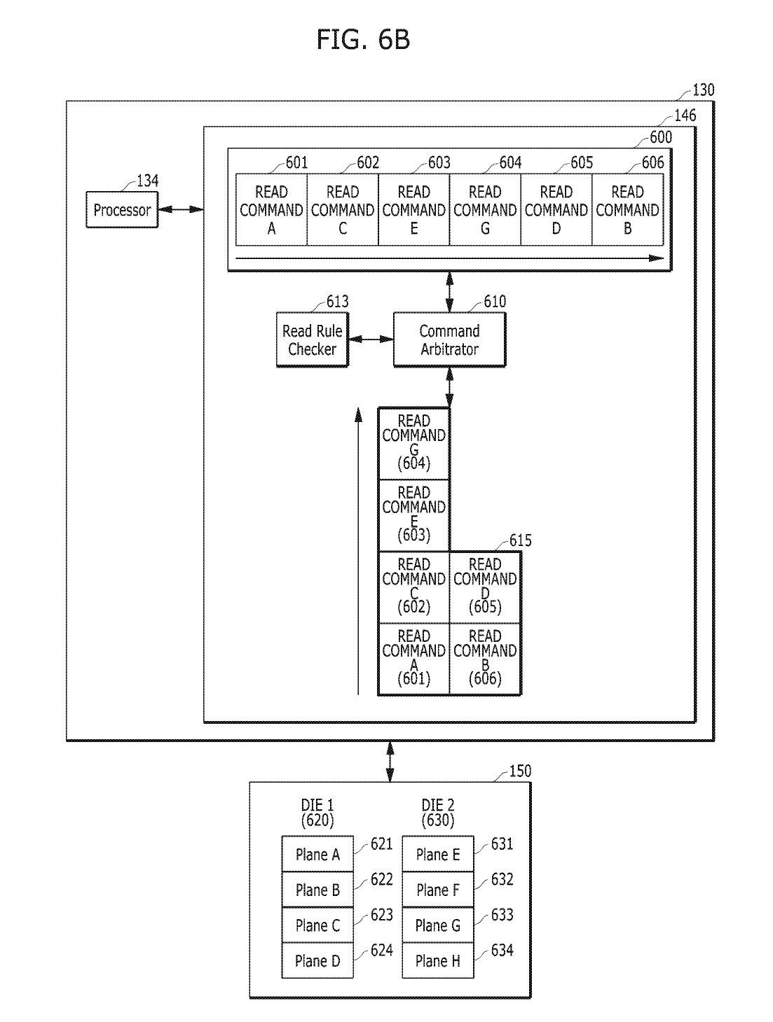

FIGS. 6A and 6B are diagrams schematically illustrating the controller 130 and the memory device 150 efficiently performing a random read operation according to an embodiment of the present invention.

The controller 130 may further include a multi-command read unit 146. The multi-command read unit 146 may include a random command queue 600, a command arbitrator 610, a read rule checker 613, and a multi-read command queue 615.

Referring to FIG. 6A, the processor 134 may transmit the random read command received from the host 102 to the multi-command read unit 146.

The random read command transmitted to the multi-command read unit 146 may be queued to the random command queue 600. A plurality of random read commands such as a read command A 601, a read command C 602, a read command E 603, a read command F 604, a read command D 605, and a read command B 606 may be queued to the random command queue 600 in order of reception.

The command arbitrator 610 may merge the plurality of random read commands queued in the random command queue 600 according to a multi-plane read rule stored in the read rule checker 613 and may input the merged random read commands to the multi-read command queue 615.

In a multi-plane read operation of reading data from a plurality of planes included in the memory device 150, the read rule checker 613 may store the multi-plane read rule representing a direction for selecting two or more among the plurality of planes as a target of the multi-plane read operation.

In an embodiment, the multi-read rule may represent a direction for selecting two or more adjacent planes among the plurality of planes in each of the first and second memory dies 620 and 630 as a target of a multi-plane read operation.

Accordingly, the command arbitrator 610 may merge the random read commands for the plane A 621 and the plane B 622 of the first memory die 620, which are selected according to the multi-read rule, and may input the merged read commands to the multi-read command queue 615.

Furthermore, the command arbitrator 610 may merge the random read commands for the plane C 623 and the plane D 624 of the first memory die 620, which are selected according to the multi-read rule, and may input the merged read commands to the multi-read command queue 615.

Furthermore, the command arbitrator 610 may merge the read commands for the plane E 631 and the plane F 632 of the second memory die 630, which are selected according to the multi-read rule, and may input the merged read commands to the multi-read command queue 615.

As such, the command arbitrator 610 may merge a plurality of random read commands (e.g., the read command A 601, the read command C 602, the read command E 603, the read command F 604, the read command D 605, and the read command B 606) queued to the random command queue 600 according to the multi-read rule and may input the merged read commands to the multi-read command queue 615.

The queueing order of the merged read commands in the multi-read command queue 615 may vary according to a system design.

Because the read command A 601 and the read command B 606 are the read commands conforming to the multi-read rule, the command arbitrator 610 may merge the read command A 601 and the read command B 606 and may input the merged read commands to the multi-read command queue 615.

Because the read command C 602 and the read command D 605 are the read commands conforming to the multi-read rule, the command arbitrator 610 may merge the read command C 602 and the read command D 605 and may input the merged read commands to the multi-read command queue 615.

Because the read command E 603 and the read command F 604 are the read commands conforming to the multi-read rule, the command arbitrator 610 may merge the read command E 603 and the read command F 604 and may input the merged read commands to the multi-read command queue 615.

In accordance with the read command A 601 and the read command B 606 that are merged and input to the multi-read command queue 615, the controller 130 may control the memory device 150 to perform a multi-read operation on the plane A 621 and the plane B 622 included in the first memory die 620 through the processor 134.

In accordance with the read command C 602 and the read command D 605 that are merged and input to the multi-read command queue 615, the controller 130 may control the memory device 150 to perform a multi-read operation on the plane C 623 and the plane D 624 included in the first memory die 620 through the processor 134.

In accordance with the read command E 603 and the read command F 605 that are merged and input to the multi-read command queue 615, the controller 130 may control the memory device 150 to perform a multi-read operation on the plane E 631 and the plane F 632 included in the second memory die 630 through the processor 134.

Referring to FIG. 6B, the random read command transmitted to the multi-command read unit 146 may be queued to the random command queue 600. A plurality of random read commands such as a read command A 601, a read command C 602, a read command E 603, a read command G 604, a read command D 605, and a read command B 606 may be queued to the random command queue 600 in order of reception.

As described above, in each of the first memory die 620 and the second memory die 630, the multi-read rule determined by the read rule checker 613 may represent a direction for selecting two or more adjacent planes among the plurality of planes in each of the first and second memory dies 620 and 630 as a target of a multi-plane read operation.

Accordingly, the command arbitrator 610 may merge the random read commands for the plane A 621 and the plane B 622 of the first memory die 620, which are selected according to the multi-read rule, and may input the merged read commands to the multi-read command queue 615.

Furthermore, the command arbitrator 610 may merge the random read commands for the plane C 623 and the plane D 624 of the first memory die 620, which are selected according to the multi-read rule, and may input the merged read commands to the multi-read command queue 615.

Because the plane E 631 and the plane G 633 corresponding to the read command E 603 and the read command G 604 do not satisfy the multi-read rule, the command arbitrator 610 may input the read command E 603 and the read command G 604 to the multi-read command queue 615 without merging the read command E 603 and the read command G 604.

In accordance with the read command A 601 and the read command B 606 that are merged and input to the multi-read command queue 615, the controller 130 may control the memory device 150 to perform a multi-read operation on the plane A 621 and the plane B 622 included in the first memory die 620 through the processor 134.

In accordance with the read command C 602 and the read command D 605 that are merged and input to the multi-read command queue 615, the controller 130 may control the memory device 150 to perform a multi-read operation on the plane C 623 and the plane D 624 included in the first memory die 620 through the processor 134.

In accordance with the read command E 603 and the read command G 604 that are not merged and input to the multi-read command queue 615, the controller 130 may control the memory device 150 to perform a single-read operation on each of the planes E 631 and G 633 included in the second memory die 630 through the processor 134.

Thus, according to the multi-read rule and the plurality of random read commands queued to the random command queue 600, a single read operation or a multiple read operation may be performed.

The queueing order of the merged and non-merged read commands in the multi-read command queue 615 may vary according to a system design.

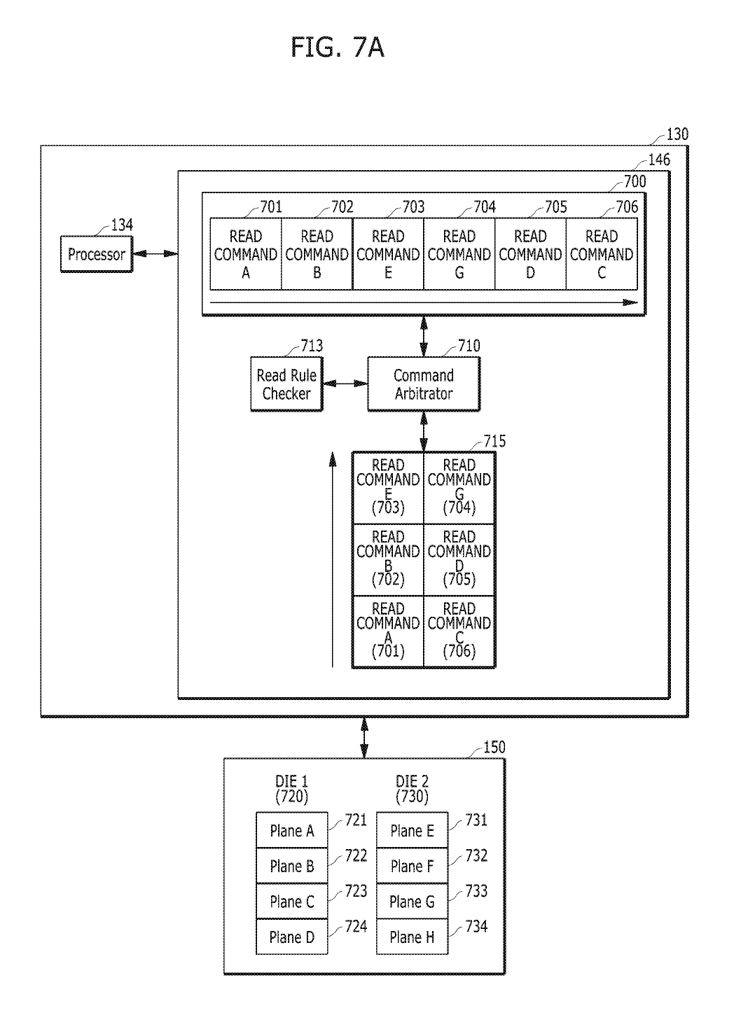

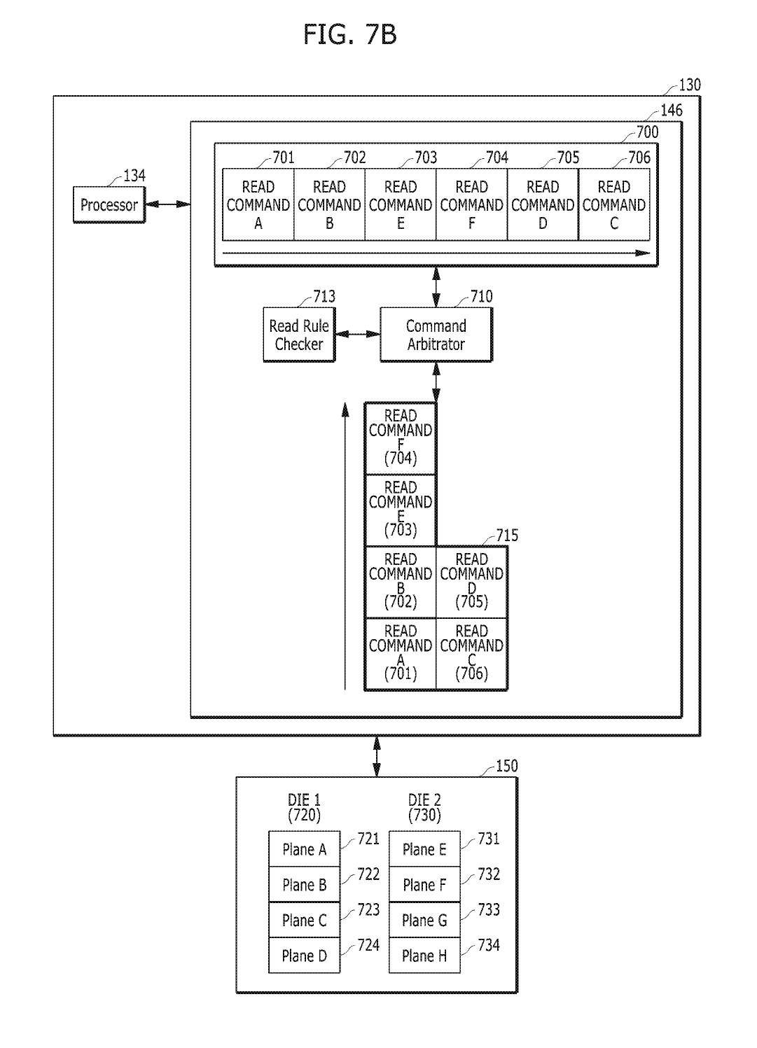

FIGS. 7A and 7B are diagrams schematically illustrating the controller 130 and the memory device 150 efficiently performing a random read operation according to an embodiment of the present invention.

Referring to FIG. 7A, the processor 134 may transmit the random read command received from the host 102 to the multi-command read unit 146.

The multi-command read unit 146 may include a random command queue 700, a command arbitrator 710, a read rule checker 713, and a multi-read command queue 715.

The random read command transmitted to the multi-command read unit 146 may be queued to the random command queue 700. A plurality of random read commands such as a read command A 701, a read command B 702, a read command E 703, a read command G 704, a read command D 705, and a read command C 706 may be queued to the random command queue 700 in order of reception.

According to the read rule stored in the read rule checker 713, the command arbitrator 710 may merge the plurality of random read commands queued to the random command queue 700 and may input the merged read commands to the multi-read command queue 715.

In a multi-plane read operation of reading data from a plurality of planes included in the memory device 150, the read rule checker 713 may store the multi-plane read rule representing a direction for selecting two or more among the plurality of planes as a target of the multi-plane read operation.

In an embodiment, the multi-read rule may represent a direction for selecting two or more non-adjacent planes among the plurality of planes in each of the first and second memory dies 720 and 730 as a target of a multi-plane read operation.

According to the multi-read rule, the command arbitrator 710 may merge the random read commands for the plane A 721 and the plane C 723 of the first memory die 720, which are selected according to the multi-read rule, and may input the merged read commands to the multi-read command queue 715.

According to the multi-read rule, the command arbitrator 710 may merge the random read commands for the plane B 722 and the plane D 724 of the first memory die 720, which are selected according to the multi-read rule, and may input the merged read commands to the multi-read command queue 715.

According to the multi-read rule, the command arbitrator 710 may merge the random read commands for the plane E 731 and the plane G 733 of the second memory die 730, which are selected according to the multi-read rule, and may input the merged read commands to the multi-read command queue 715.

The command arbitrator 710 may merge a plurality of random read commands (for example, the read command A 701, the read command B 702, the read command E 703, the read command G 704, the read command D 705, and the read command C 706) queued to the random command queue 700 according to the multi-read rule and may input the merged read commands to the multi-read command queue 715.

The queueing order of the merged read commands in the multi-read command queue 615 may vary according to a system design.

Because the read command A 701 and the read command C 706 are the read commands conforming to the multi-read rule, the command arbitrator 710 may merge the read command A 701 and the read command C 706 and may input the merged read commands to the multi-read command queue 715.

Because the read command B 702 and the read command D 705 are the read commands conforming to the multi-read rule, the command arbitrator 710 may merge the read command B 702 and the read command D 705 and may input the merged read commands to the multi-read command queue 715.

Because the read command E 703 and the read command G 704 are the read commands conforming to the multi-read rule, the command arbitrator 710 may merge the read command E 703 and the read command G 704 and may input the merged read commands to the multi-read command queue 715.

In accordance with the read command A 701 and the read command C 706 that are merged and input to the multi-read command queue 715, the controller 130 may control the memory device 150 to perform a multi-read operation on the plane A 721 and the plane C 723 included in the first memory die 720 through the processor 134.

In accordance with the read command B 702 and the read command D 705 that are merged and input to the multi-read command queue 715, the controller 130 may control the memory device 150 to perform a multi-read operation on the plane B 722 and the plane D 724 included in the first memory die 720 through the processor 134.

In accordance with the read command E 703 and the read command G 704 that are merged and input to the multi-read command queue 715, the controller 130 may control the memory device 150 to perform a multi-read operation on the plane E 731 and the plane G 733 included in the second memory die 730 through the processor 134.

Referring to FIG.7B, the random read command transmitted to the multi-command read unit 146 may be queued to the random command queue 700. A plurality of random read commands such as a read command A 701, a read command B 702, a read command E 703, a read command F 704, a read command D 705, and a read command C 706 may be queued to the random command queue 700 in order of reception.

As described above, in each of the first memory die 720 and the second memory die 730, the multi-read rule stored in the read rule checker 713 may represent a direction for selecting two or more non-adjacent planes among the plurality of planes in each of the first and second memory dies 720 and 730 as a target of a multi-plane read operation.

According to the multi-read rule, the command arbitrator 710 may merge the random read commands for the plane A 721 and the plane C 723 of the first memory die 720, which are selected according to the multi-read rule, and may input the merged read commands to the multi-read command queue 715.

According to the multi-read rule, the command arbitrator 710 may merge the random read commands for the plane B 722 and the plane D 724 of the first memory die 720, which are selected according to the multi-read rule, and may input the merged read commands to the multi-read command queue 715.

Because the plane E 731 and the plane F 732 corresponding to the read command E 703 and the read command F 704 do not satisfy the multi-read rule, the command arbitrator 710 may input the read command E 703 and the read command F 704 to the multi-read command queue 715 without merging the read command E 703 and the read command F 704.

In accordance with the read command A 701 and the read command C 706 that are merged and input to the multi-read command queue 715, the controller 130 may control the memory device 150 to perform a multi-read operation on the plane A 721 and the plane C 723 included in the first memory die 720 through the processor 134.

In accordance with the read command B 702 and the read command D 705 that are merged and input to the multi-read command queue 715, the controller 130 may control the memory device 150 to perform a multi-read operation on the plane B 722 and the plane D 724 included in the first memory die 720 through the processor 134.

In accordance with the read command E 703 and the read command F 704 that are not merged and input to the multi-read command queue 715, the controller 130 may control the memory device 150 to perform a single-read operation on each of the planes E 731 and F 732 included in the second memory die 630 through the processor 134.

Thus, a single read operation or a multiple read operation may be performed according to the multi-read rule and the plurality of random read commands queued to the random command queue 700.

The queueing order of the merged and non-merged read commands in the multi-read command queue 615 may vary according to a system design.

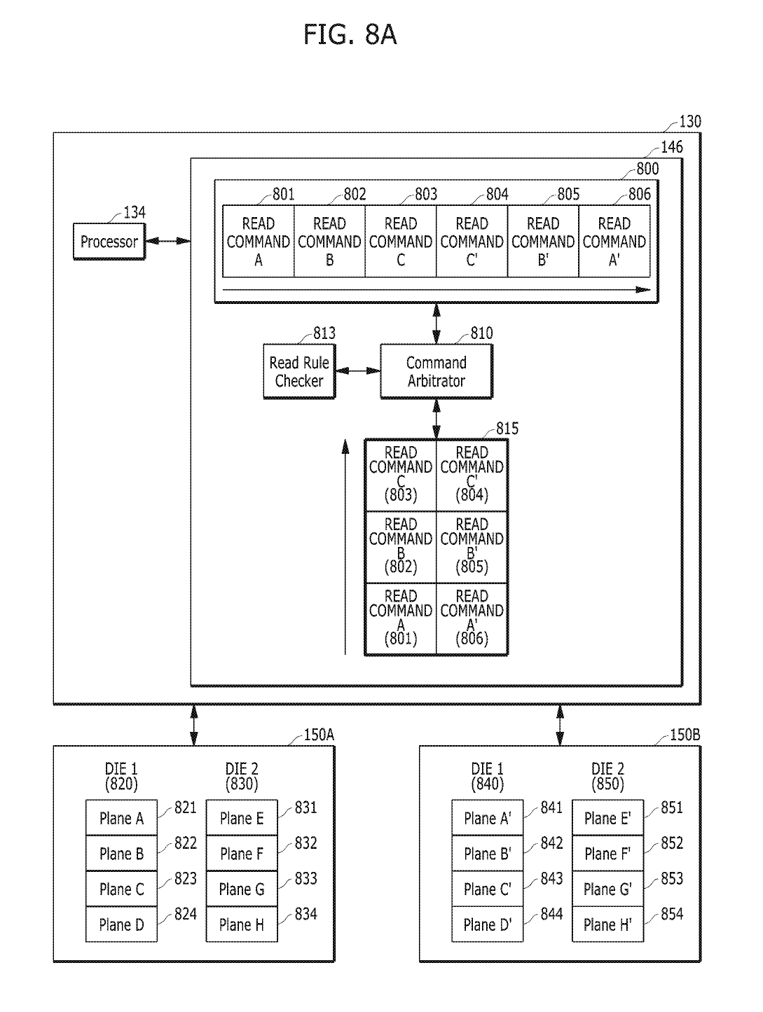

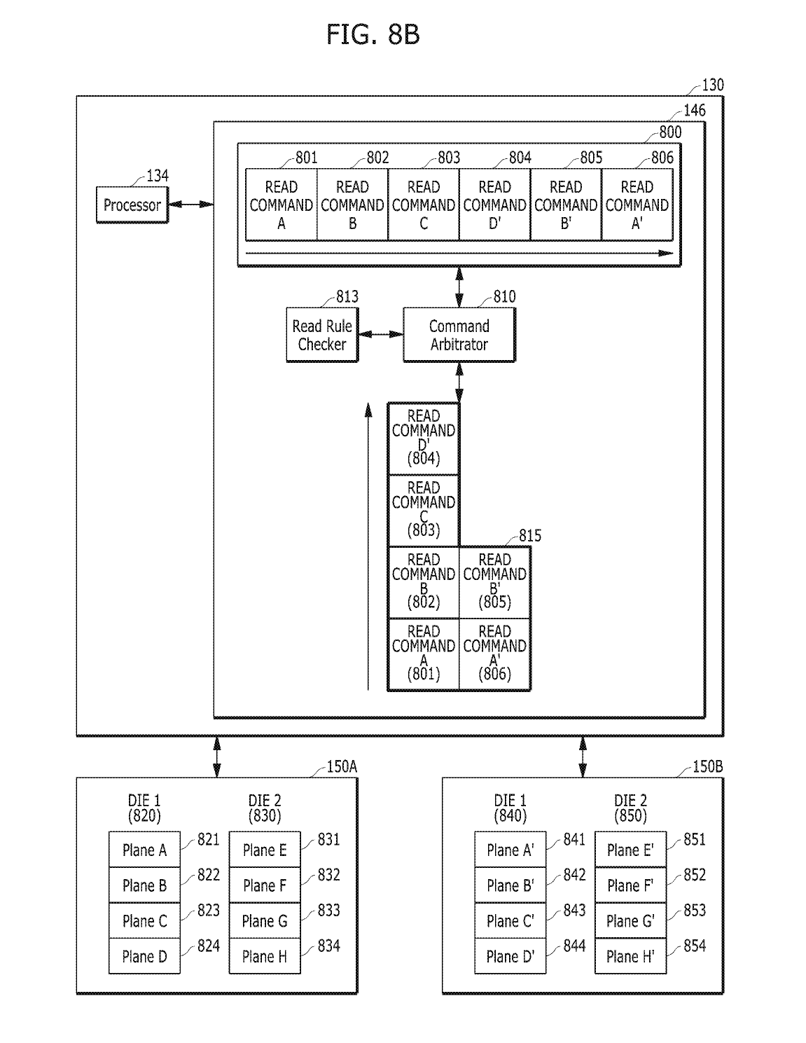

FIGS. 8A and 8B are diagrams schematically illustrating the controller 130 and the memory device 150 efficiently performing a random read operation according to an embodiment of the present invention.

Referring to FIG. 8A, the controller 130 may control a plurality of memory devices 150A and 150B to perform a read operation through the processor 134.

The processor 134 may transmit the random read command received from the host 102 to the multi-command read unit 146.

The multi-command read unit 146 may be composed a random command queue 800, a command arbitrator 810, a read rule checker 813, and a multi-read command queue 815.

The random read command transmitted to the multi-command read unit 146 may be queued to the random command queue 800. A plurality of random read commands such as a read command A 801, a read command B 802, a read command C 803, a read command C′ 804, a read command B′ 805, and a read command A′ 806 may be queued to the random command queue 800 in order of reception.

According to the read rule of the read rule checker 813, the command arbitrator 810 may merge the plurality of random read commands queued to the random command queue 800 and may input the merged read commands to the multi-read command queue 815.

In a multi-plane read operation of reading data from a plurality of planes included in the plurality of memory devices 150A and 150B, the read rule checker 813 may store the multi-plane read rule representing a direction for selecting two or more among the plurality of planes as a target of the multi-plane read operation.

In an embodiment, the multi-read rule may represent a direction for selecting two or more same planes of different memory devices, respectively, among the plurality of planes of the plurality of memory devices 150A and 150B as a target of a multi-plane read operation.

According to the multi-read rule, the command arbitrator 810 may merge the random read commands for the plane A 821 of the first memory die 820 included in the first memory device 150A and the plane A′ 841 of the second memory die 830 included in the second memory device 150B, which are selected according to the multi-read rule, and may input the merged read commands to the multi-read command queue 815.

According to the multi-read rule, the command arbitrator 810 may merge the random read commands for the plane B 822 of the first memory die 820 included in the first memory device 150A and the plane B′ 842 of the second memory die 830 included in the second memory device 150B, which are selected according to the multi-read rule, and may input the merged read commands to the multi-read command queue 815.

According to the multi-read rule, the command arbitrator 810 may merge the random read commands for the plane C 823 of the first memory die 820 included in the first memory device 150A and the plane C′ 843 of the second memory die 830 included in the second memory device 150B, which are selected according to the multi-read rule, and may input the merged read commands to the multi-read command queue 815.

The command arbitrator 810 may merge a plurality of random read commands (e.g., the read command A 801, the read command B 802, the read command C 803, the read command C′ 804, the read command B′ 805, and the read command A′ 806) queued to the random command queue 800 according to the multi-read rule and may input the merged read commands to the multi-read command queue 815.

The queueing order of the merged read commands in the multi-read command queue 615 may vary according to a system design.

Because the read command A 801 and the read command A′ 806 are the read commands conforming to the multi-read rule, the command arbitrator 810 may merge the read command A 801 and the read command A′ 806 and may input the merged read commands to the multi-read command queue 815.

Because the read command B 802 and the read command B′ 805 are the read commands conforming to the multi-read rule, the command arbitrator 810 may merge the read command B 802 and the read command B′ 805 and may input the merged read commands to the multi-read command queue 815.

Because the read command C 803 and the read command C′ 804 are the read commands conforming to the multi-read rule, the command arbitrator 810 may merge the read command C 803 and the read command C′ 804 and may input the merged read commands to the multi-read command queue 815.

In accordance with the read command A 801 and the read command A′ 806 that are merged and input to the multi-read command queue 815, the controller 130 may control the memory device 150 to perform a multi-read operation on the plane A 821 included in the first memory die 820 of the first memory device 150A and the plane A′ 841 included in the first memory die 840 of the second memory device 150B through the processor 134.

In accordance with the read command B 802 and the read command B′ 805 that are merged and input to the multi-read command queue 815, the controller 130 may control the memory device 150 to perform a multi-read operation on the plane B 822 included in the first memory die 820 of the first memory device 150A and the plane B′ 842 included in the first memory die 840 of the second memory device 150B through the processor 134.

In accordance with the read command C 803 and the read command C′ 804 that are merged and input to the multi-read command queue 815, the controller 130 may control the memory device 150 to perform a multi-read operation on the plane C 823 included in the first memory die 820 of the first memory device 150A and the plane C′ 843 included in the first memory die 840 of the second memory device 150B through the processor 134.

Referring to FIG.8B, the random read command transmitted to the multi-command read unit 146 may be queued to the random command queue 800. A plurality of random read commands such as a read command A 801, a read command B 802, a read command C 803, a read command D′ 804, a read command B′ 805, and a read command A′ 806 may be queued to the random command queue 800 in order of reception.

As described above, in each of the first memory die 820 and the second memory die 830 included in the first memory device 150A and each of the first memory die 840 and the second memory die 850 included in the second memory device 150B, the multi-read rule may represent a direction for selecting two or more same planes of different memory devices, respectively, among the plurality of planes of the plurality of memory devices 150A and 150B as a target of a multi-plane read operation.

According to the multi-read rule, the command arbitrator 810 may merge the read commands for the plane A 821 of the first memory die 820 included in the first memory device 150A and the plane A′ 841 of the first memory die 840 included in the second memory device 150B, which are selected according to the multi-read rule, and may input the merged read commands to the multi-read command queue 815.

According to the multi-read rule, the command arbitrator 810 may merge the random read commands for the plane B 822 of the first memory die 820 included in the first memory device 150A and the plane B′ 842 of the first memory die 840 included in the second memory device 150B, which are selected according to the multi-read rule, and may input the merged read commands to the multi-read command queue 815.

Because the plane C 823 and the plane D′ 844 corresponding to the read command C 803 and the read command D′ 804 do not satisfy the multi-read rule, the command arbitrator 810 may input the read command C 803 and the read command D′ 804 to the multi-read command queue 815 without merging the read command C 803 and the read command D′ 804 to perform a single read operation.

In accordance with the read command A 801 and the read command A′ 806 that are merged and input to the multi-read command queue 815, the controller 130 may control the memory device 150 to perform a multi-read operation on the plane A 821 included in the first memory die 820 of the first memory device 150A and the plane A′ 841 included in the first memory die 840 of the second memory device 150B through the processor 134.

In accordance with the read command B 802 and the read command B′ 805 that are merged and input to the multi-read command queue 815, the controller 130 may control the memory device 150 to perform a multi-read operation on the plane B 822 included in the first memory die 820 of the first memory device 150A and the plane B′ 842 included in the first memory die 840 of the second memory device 150B through the processor 134.

In accordance with the read command C 803 and the read command D′ 804 that are not merged and input to the multi-read command queue 715, the controller 130 may control the memory device 150 to perform a single-read operation on each of the plane C 823 of the first memory die 820 in the first memory device 150A and plane D′ 844 of the first memory die 840 included in the second memory device 150B through the processor 134.

Thus, a single read operation or a multiple read operation may be performed according to the multi-read rule and the plurality of random read commands queued to the random command queue 800.

The queueing order of the merged and non-merged read commands in the multi-read command queue 615 may vary according to a system design.

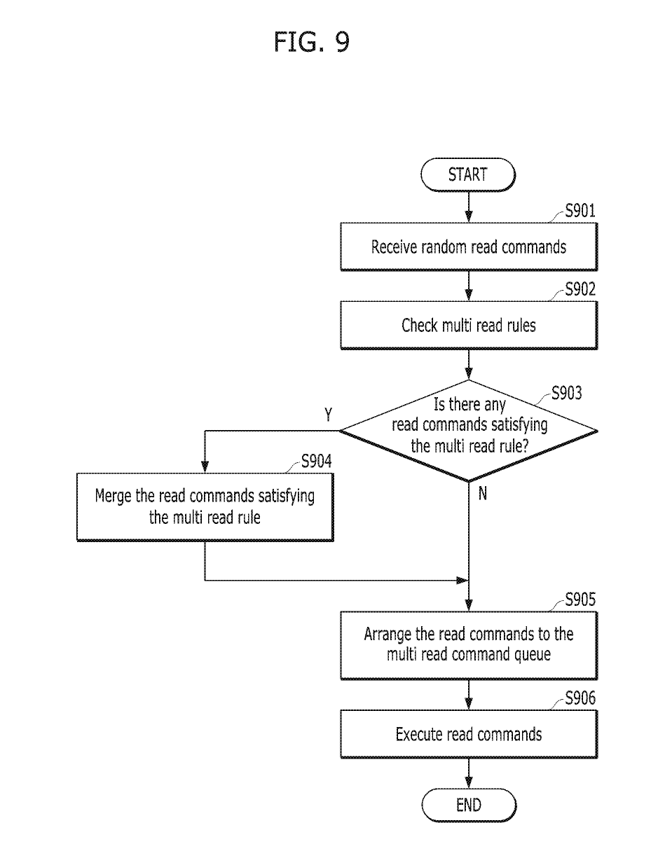

FIG. 9 is a flowchart illustrating a multi-plane read operation performed in a memory system according to an embodiment of the present invention. In describing the multi-plane read operation according to an embodiment of the present invention, “random command queue” in FIG. 9 may correspond to the random command queue 600, 700, or 800 of FIGS. 6 to 8, respectively.

Further, “command arbitrator” in FIG. 9 may correspond to the command arbitrator 610, 710, or 810 of FIGS. 6 to 8, respectively. Further, “read rule checker” in FIG. 9 may correspond to the read rule checker 613, 713, or 813 of FIGS. 6 to 8, respectively. Further, “multi-read command queue” in FIG. 9 may refer to the multi-read command queue 615, 715, or 815 of FIGS. 6 to 8, respectively.

At step S901, the processor 134 may transmit the random read commands received from the host 102 to the multi-command read unit 146. The multi-command read unit 146 may queue the random read commands in the random command queue. The plurality of random read commands may be queued in the random command queue in order of reception.

At step S902, the command arbitrator may check the multi-read rules stored in the read rule checker.

In an embodiment, the multi-read rule may represent a direction for selecting two or more adjacent planes among the plurality of planes in each of the first and second memory dies 620 and 630 as a target of a multi-plane read operation, as described above with reference to FIGS. 6A and 6B.

In an embodiment, the multi-read rule may represent a direction for selecting two or more non-adjacent planes among the plurality of planes in each of the first and second memory dies 720 and 730 as a target of a multi-plane read operation, as described above with reference to FIGS. 7A and 7B.

In an embodiment, the multi-read rule may represent a direction for selecting two or more same planes of different memory devices, respectively, among the plurality of planes of the plurality of memory devices 150A and 150B as a target of a multi-plane read operation, as described above with reference to FIGS. 8A and 8B.

In addition to the above-described multi-read rules, the multi-read rules may be defined in various ways for a multi-read operation.

At step S903, the command arbitrator may detect the random read commands satisfying the multi-read rule among the random read commands queued in the random command queue.

At step S904, the command arbitrator may merge the detected random read commands satisfying the multi read rule (that is, “Y” at step S903).

At step S905, the command arbitrator may input the merged read commands and remaining random read commands of the random command queue into the multi-read command queue.

At step S906, in accordance with the multi-read commands input to the multi-read command queue, the controller 130 may control the memory device(s) 150, and 150A and 150B to perform a multi-read operation on the planes included in the memory dies of the memory device(s) 150, and 150A and 150B through the processor 134. Furthermore, in accordance with the non-merged random read commands input to the multi-read command queue, the controller 130 may control the memory device(s) 150, and 150A and 150B to perform a single read operation on the planes included in the memory die of the memory device(s) 150, and 150A and 150B through the processor 134.

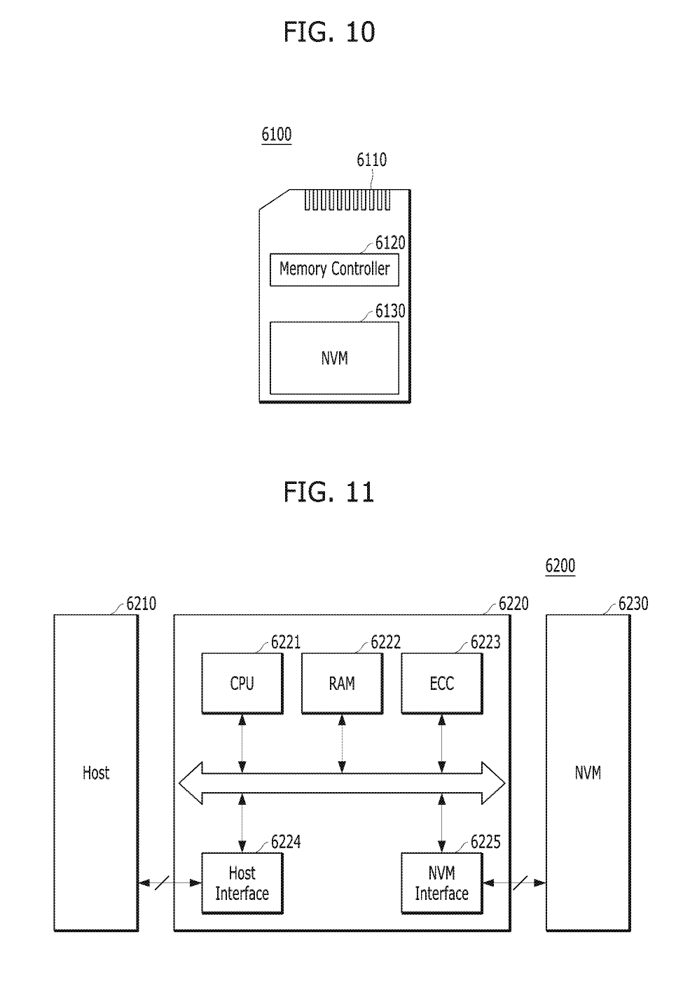

FIGS. 10 to 18 are diagrams schematically illustrating application examples of the data processing system of FIGS. 1 to 9 according to various embodiments.

FIG. 10 is a diagram schematically illustrating another example of the data processing system including the memory system in accordance with the present embodiment. FIG. 10 schematically illustrates a memory card system to which the memory system in accordance with the present embodiment is applied.

Referring to FIG. 10, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 to 9, and the memory device 6130 may correspond to the memory device 150 of the memory system 110 described with reference to FIGS. 1 to 9.

Thus, the memory controller 6120 may include a RAM, a processing unit, a host interface, a memory interface and an error correction unit. The memory controller 130 may further include the elements described in FIG. 1.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM). The memory device 6130 may include a plurality of dies as in the memory device 150 of FIG. 1.

The memory controller 6120 and the memory device 6130 may be integrated into a single semiconductor device. For example, the memory controller 6120 and the memory device 6130 may construct a solid state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 11 is a diagram schematically illustrating another example of the data processing system including a memory system, in accordance with the present embodiment.

Referring to FIG. 11, the data processing system 6200 may include a memory device 6230 having one or more nonvolatile memories and a memory controller 6220 for controlling the memory device 6230. The data processing system 6200 illustrated in FIG. 11 may serve as a storage medium such as a memory card (CF, SD, micro-SD or the like) or USB device, as described with reference to FIG. 1. The memory device 6230 may correspond to the memory device 150 in the memory system 110 described in FIGS. 1 to 9, and the memory controller 6220 may correspond to the controller 130 in the memory system 110 described in FIGS. 1 to 9.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control the operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 illustrated in FIG. 1 As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with the present embodiment may be applied to wired/wireless electronic devices or particularly a mobile electronic device.

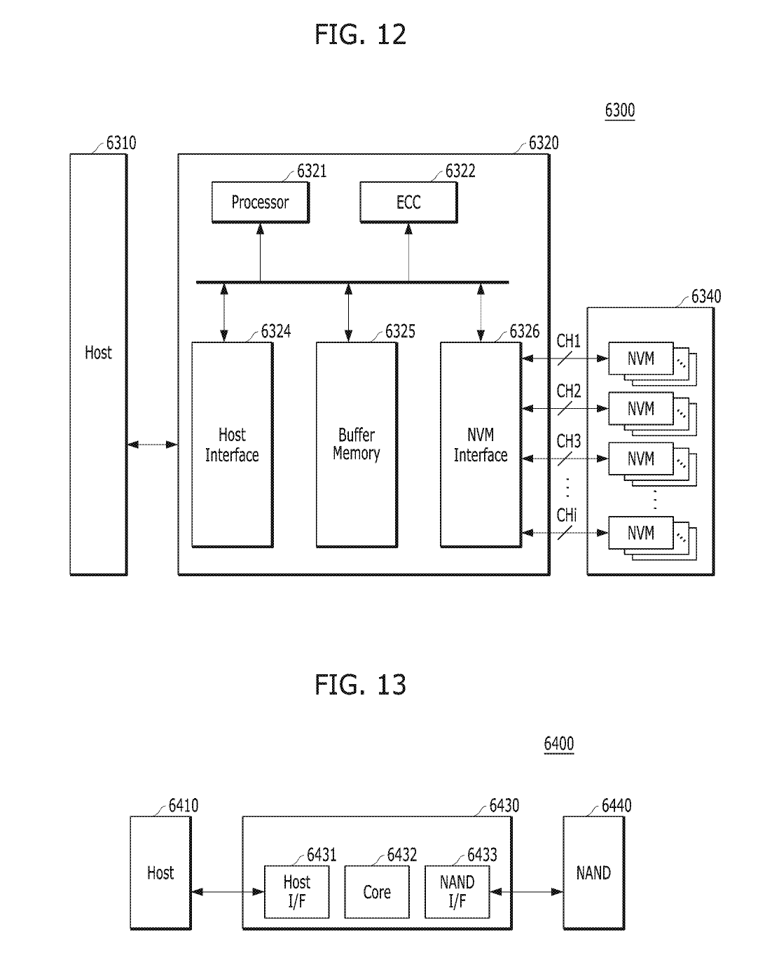

FIG. 12 is a diagram schematically illustrating another example of the data processing system including the memory system in accordance with the present embodiment. FIG. 12 schematically illustrates an SSD to which the memory system in accordance with the present embodiment is applied.

Referring to FIG. 12, the SSD 6300 may include a controller 6320 and a memory device 6340 including a plurality of nonvolatile memories. The controller 6320 may correspond to the controller 130 in the memory system 110 of FIG. 1, and the memory device 6340 may correspond to the memory device 150 in the memory system of FIG. 1.

More specifically, the controller 6320 may be connected to the memory device 6340 through a plurality of channels CH1 to CHi.

The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta-data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 10 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIG. 1 is applied may be provided to embody a data processing system, for example, RAID (Redundant Array of

Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 13 is a diagram schematically illustrating another example of the data processing system including the memory system in accordance with an embodiment. FIG. 13 schematically illustrates an embedded Multi-Media Card (eMMC) to which the memory system in accordance with an embodiment is applied.

Referring to FIG. 13, the eMMC 6400 may include a controller 6430 and a memory device 6440 embodied by one or more NAND flash memories. The controller 6430 may correspond to the controller 130 in the memory system 110 of FIG. 1, and the memory device 6440 may correspond to the memory device 150 in the memory system 110 of FIG. 1.

More specifically, the controller 6430 may be connected to the memory device 6440 through a plurality of channels. The controller 6430 may include one or more cores 6432, a host interface 6431 and a memory interface, for example, a NAND interface 6433.

The core 6432 may control the operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

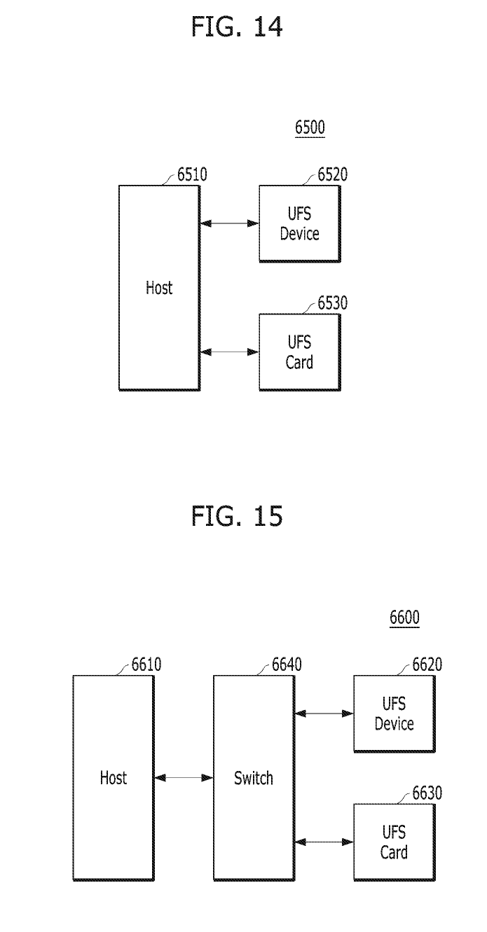

FIGS. 14 to 17 are diagrams schematically illustrating other examples of the data processing system including the memory system in accordance with an embodiment. FIGS. 14 to 17 schematically illustrate UFS (Universal Flash Storage) systems to which the memory system in accordance with an embodiment is applied.

Referring to FIGS. 14 to 17, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIG. 1. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 11 to 13, and the UFS cards 6530, 6630, 6730 and 6830 may be embodied in the form of the memory card system 6100 described with reference to FIG. 8.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 14, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. At this time, the UFS device 6520 and the UFS card 6530 may communicate with each other through link layer switching at the UniPro of the host 6510. In the present embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

In the UFS system 6600 illustrated in FIG. 15, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

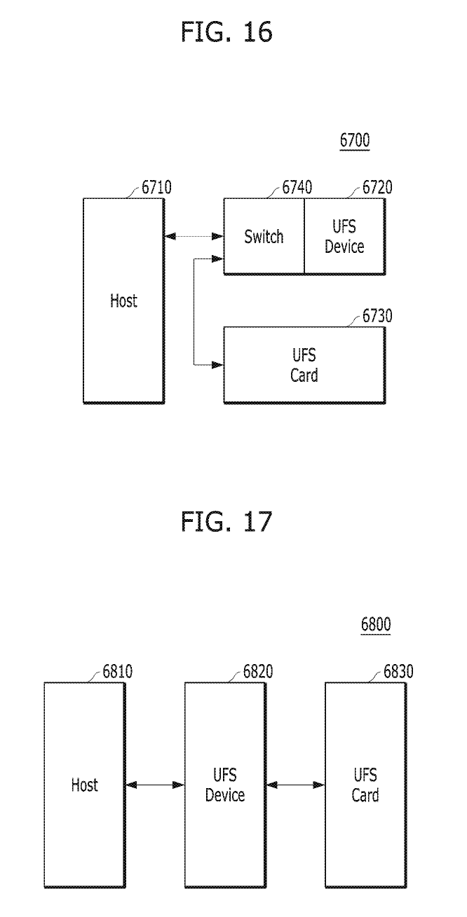

In the UFS system 6700 illustrated in FIG. 16, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 17, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. At this time, the host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

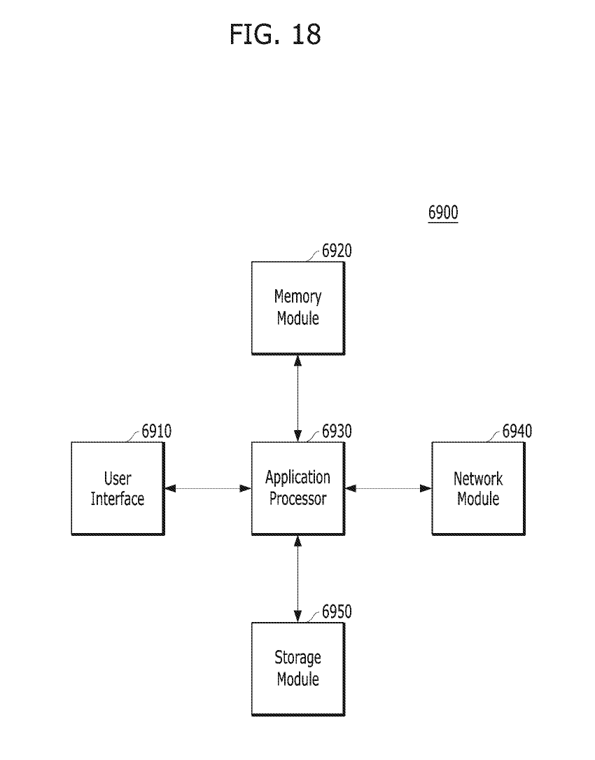

FIG. 18 is a diagram schematically illustrating another example of the data processing system including the memory system in accordance with an embodiment. FIG. 18 is a diagram schematically illustrating a user system to which the memory system in accordance with an embodiment is applied.

Referring to FIG. 18, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as a System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but may also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIG. 1. Furthermore, the storage module 6950 may be embodied as an SSD, eMMC and UFS as described above with reference to FIGS. 10 to 17.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIG. 1 is applied to a mobile electronic device of the user system 6900, the application processor 6930 may control the operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

While the present invention has been described with respect to specific embodiments, it will be apparent to those skilled in the art that various changes and modifications may be made without departing from the spirit and scope of the invention as defined in the following claims.

What is claimed is:

1. A memory system comprising:
one or more memory devices each including a plurality of memory dies each having a plurality of planes; and
a controller including:
a random command queue suitable for queueing a plurality of random read commands;
a multi-read command queue suitable for queueing at least merged random read commands;
a read rule checker suitable for storing a multi-read rule representing a direction for selecting two or more among the planes;
a command arbitrator suitable for merging two or more random read commands satisfying the multi-read rule among the random read commands queued in the random read commands, and queueing at least the merged random read commands in the multi-read command queue; and
a processor suitable for controlling the memory devices to perform a multi-plane read operation according to the merged random read commands in the multi-read command queue.

2. The memory system of claim 1, wherein the multi-read rule is a read rule for performing a multi-read operation on the read units close to each other among a plurality of read units included in the first memory device.

3. The memory system of claim 1, wherein the multi-read rule is a read rule for performing a multi-read operation on the read units not close to each other among a plurality of read units included in the first memory device.

4. The memory system of claim 1, wherein the multi-read rule unit is a read rule for performing a multi-read operation for read units included in different memory devices and corresponding to each other.

5. The memory system of claim 1, wherein the processor controls the memory devices to further perform a single read operation in accordance with a random read command input to the multi-read command queue and other than the merged random read commands.

6. An operating method of memory system including one or more memory devices each including a plurality of memory dies each having a plurality of planes, the method comprising:
queueing a plurality of random read commands into a random command queue;
merging two or more random read commands satisfying a multi-read rule, which represents a direction for selecting two or more among the planes, among the random read commands queued in the random read commands;
queueing at least the merged random read commands in a multi-read command queue; and
controlling the memory devices to perform a multi-plane read operation according to the merged random read commands in the multi-read command queue.

7. The operating method of claim 6, wherein the multi-read rule is a read rule for performing a multi-read operation on the read units close to each other among a plurality of read units included in the first memory device.

8. The operating method of claim 6, wherein the multi-read rule is a read rule for performing a multi-read operation on the read units not close to each other among a plurality of read units included in the first memory device.

9. The operating method of claim 6, wherein the multi-read rule unit is a read rule for performing a multi-read operation for read units included in different memory devices and corresponding to each other.

10. The operating method of claim 6, further comprising controlling the memory devices to perform a single read operation in accordance with a random read command input to the multi-read command queue and other than the merged random read commands.

11. A memory system comprising:
one or more memory devices each including a plurality of memory dies each having a plurality of planes; and
a controller suitable for:
selecting two or more planes among the plurality of planes;
merging random read commands corresponding to the selected planes; and
controlling the memory devices to perform a multi-plane read operation according to the merged random read commands.

12. The memory system of claim 11, wherein the controller selects two or more adjacent planes among the plurality of planes of the respective memory dies in the respective memory devices.

13. The memory system of claim 11, wherein the controller selects two or more non-adjacent planes among the plurality of planes of the respective memory dies in the respective memory devices.

14. The memory system of claim 11, wherein the controller selects two or more same planes of different memory devices, respectively, among the plurality of planes of the memory dies in the memory devices.

15. An operating method of a memory system including one or more memory devices each including a plurality of memory dies each having a plurality of planes, the method comprising:
selecting two or more planes among the plurality of planes;
merging random read commands corresponding to the selected planes; and
controlling the memory devices to perform a multi-plane read operation according to the merged random read commands.

16. The operating method of memory system of claim 15, wherein the selecting includes selecting two or more adjacent planes among the plurality of planes of the respective memory dies in the respective memory devices.

17. The operating method of memory system of claim 15, wherein the selecting includes selecting two or more non-adjacent planes among the plurality of planes of the respective memory dies in the respective memory devices.

18. The operating method of memory system of claim 15, wherein the selecting includes selecting two or more same planes of different memory devices, respectively, among the plurality of planes of the memory dies in the memory devices.
